(19) United States
(12) Patent Application Publication
(10) Pub. No.: US 2016/0181459 A1
(43) Pub. Date: Jun. 23, 2016

(54) METHOD FOR INCREASING THE DYNAMIC RANGE OF A SILICON PHOTOMULTIPLIER

(71) Applicant: Leica Microsystems CMS GmbH, Wetzlar (DE)

(72) Inventors: Holger BIRK, Meckesheim (DE); Volker SEYFRIED, Nussloch (DE)

(21) Appl. No.: 14/973,786

(22) Filed: Dec. 18, 2015

(30) Foreign Application Priority Data
Dec. 19, 2014 (DE) 10 2014 119 300.8

(51) Int. Cl. H01L 31/107; H01L 31/028

(52) U.S. Cl. CPC H01L 31/107; H01L 31/028

(57) ABSTRACT

A method for increasing the dynamic range of a silicon photomultiplier (SiPM) in particular with regard to the detection of high radiation intensities, individual avalanche photodiodes usually being biased with a bias voltage V_{R} beyond a breakdown voltage V_{BR}, with the consequence of an avalanche discharge of electrons that define the output signal, is characterized in that the output signals resulting from an incident radiation intensity are adjusted by modifying the bias voltage V_{R}, the output signals being evaluated in the integration mode.

The invention relates to a method for increasing the dynamic range of a silicon photomultiplier (SiPM) in particular with regard to the detection of high radiation intensities or irradiation intensities, individual avalanche photodiodes usually being biased with a bias voltage V_{R} beyond a breakdown voltage V_{BR}, with the consequence of an avalanche discharge of electrons that define the output signal.

For purposes of the invention, “light” represents any electromagnetic radiation that can be detected with a silicon photomultiplier (SiPM), in particular visible light, infrared light, UV light, X-radiation, and gamma radiation. By way of example but without limitation, the method can be utilized in confocal fluorescence microscopy.

In confocal fluorescence microscopy in particular, sensitive light detectors are used in order to capture a sufficient quantity of fluorescent light with an optimum signal-to-noise noise ratio. Photomultiplier tubes (PMTs) have hitherto been used most often. These are special electron tubes that are suitable for detecting weak light signals, even individual photons, by generating and amplifying an electrical signal. A photomultiplier of this kind is typically made up of a photocathode and a downstream secondary electron multiplier in an evacuated glass tube. The manner of operation of a PMT is sufficiently known from the existing art that no discussion thereof is necessary.

Silicon photomultipliers (SiPMs), which usually encompass an arrangement of avalanche photodiodes (APDs) connected in parallel, have been available for some time. Avalanche photodiodes are highly sensitive “fast” photodiodes. They utilize the internal photoelectric effect for charge carrier generation, and the avalanche breakdown effect for internal gain. They can be regarded as a semiconductor equivalent to the photomultiplier, and are utilized for the detection of low radiation intensities or even individual photons. Avalanche photodiodes are designed for controlled avalanche breakdown.

Silicon photomultipliers are comparable, and by now even superior, to the classic photomultiplier in terms of both photon detection efficiency (PDE) and dark noise. They are moreover an inexpensive alternative to classic photomultipliers.

In classic photomultipliers, the gain can be modified over several orders of magnitude by influencing the applied voltage. The photomultiplier is correspondingly suitable for covering an extremely wide range of radiation intensities, i.e. of radiation power levels to be detected. In a a so-called “Geiger mode” the silicon photomultiplier is operated at a fixed voltage. This means that a photon always generates a charge pulse having approximately the same quantity of charge. The gain of a silicon photomultiplier, based on a defined applied voltage, is correspondingly fixed.

The silicon photomultiplier thus has the disadvantage, as compared with the classic photomultiplier, that the gain of the silicon photomultiplier is fixed, specifically is set to the maximum sensitivity. The result of this fixed setting is that only a small range of possible radiation intensities is covered. If the radiation intensity increases above a specific value, it can happen that the output signal no longer rises, or at least no longer rises linearly with the radiation intensity. The classic silicon photomultiplier is thus not usable for high radiation intensities.

The object on which the present invention is based is therefore to configure and refine a method for increasing the dynamic range of a silicon photomultiplier in such a way that, in particular, the detection of high radiation intensities is possible without further design outlay. Utilization of a silicon photomultiplier over a wide dynamic range is intended to be possible inexpensively, as compared with detection by means of a photomultiplier.

The aforesaid object is achieved by the features of claim 1. According to the latter, the method discussed previously is characterized in that the output signals resulting from an incident radiation intensity are adjusted by modifying the bias voltage V_{R}, the output signals being evaluated in the integration mode.

The consideration on which the invention is based in accordance with the features above, proceeding initially from the use of conventional photomultipliers, is as follows:

In photomultipliers (PMTs), an electron released at the photocathode is amplified by a cascade of typically eight to 10 dynodes, so that a measurable pulse of up to 10⁶ electrons is produced at the output of the last dynode. The total gain is the product of the individual gains from one dynode to the next, and can be modified over orders of magnitude by applying different acceleration voltages.

In a silicon photomultiplier, on the other hand, numerous individual avalanche photodiodes (APDs) are connected in parallel, and each individual APD is normally biased beyond the breakdown voltage. The high gain (typically 10⁵ to 10⁶) is produced by an individual avalanche discharge. In this operating mode, also called “Geiger mode,” the respective APD must be charged again after such a discharge.

The gain M indicates how many electrons are produced from one photoelectron in the context of the avalanche discharge (Q=charge per pulse, q=charge of an electron):

M=Q/q

In Geiger mode, the charge Q depends on the capacitance C of an individual APD and on the difference between the bias voltage V_{R} and breakdown voltage V_{BR}:

Q=C·(V_{R}−V_{BR})

There are in principle two possibilities for evaluating the output signals of an SiPM having an arrangement of APDs. In the context of a first variant the number of charge pulses per time interval can be counted, namely in so-called “counting mode.” According to a second variant the quantity of charge occurring in a time interval can be summed or integrated. This is called “integration mode.”

Working in counting mode means depending on a detected photon generating a measurable charge pulse. In counting mode it is therefore useful to keep the applied voltage V_{R} always constant, and sufficiently high to always achieve similar pulse heights, which then exceed a threshold value and can be detected.

If one then wishes to expand the restricted dynamic range of an SiPM in terms of greater radiation intensity, the only option is the integration mode. In this mode it is possible to vary the applied voltage V_{R}, contrary to how SiPMs have hitherto been used. When the applied voltage V_{R} is reduced, the charge pulses per photon become smaller. Even if an individual photon can then no longer be detected, with a sufficiently large number of incident photons the sum of the charge pulses results in a measurable signal, specifically without utilizing avalanche discharge in Geiger mode.

This means that with an SiPM as well, it is possible in principle to adjust the gain almost arbitrarily as a function of the radiation intensity to be detected. For applied voltages V_{R} below the breakdown voltage V_{BR}, the behavior of the APDs transitions to that of the hitherto usual photodiodes, i.e. without the phenomenon of avalanche gain.

The charge occurring for a specific radiation intensity incident on the SiPM can be adjusted by influencing the applied voltage V_{R}. In order to allow a silicon photomultiplier to be used effectively even at lower voltages, however, it is not just the signal height that should be capable of being adapted to the maximum incident quantity of photons. The measured signal should also be as proportional as possible to the incident quantity of photons.

The aforementioned linearity is not self-evident. It is already known, from the practical use of individual APDs, that the maximum counting rates are on the order of 10⁷ counts per second (cps). This is attributable to the fact that after each charge pulse the APD has a certain dead time during which the voltage is built back up. With an SiPM the dynamics are greater than with an individual APD, thanks to the provision of multiple APDs. But even assuming an ideal case of 1,000 parallel and uniformly illuminated APDs within an SiPM, considerable saturation effects would need to be expected at specific intensities.

Because of the smaller area of each APD in an SiPM (individual APD typically 50 μm to 250 μm in diameter, APDs in an SiPM typically 10 μm to 100 μm), and the smaller capacitance associated therewith, charging obviously takes less time than with an individual APD. There could also be a correlation between the voltage V_{R} and the required charging time.

If nonlinearities were to occur at a specified voltage V_{R} between the incident radiation intensity and measured signal, it would be possible to correct the saturation effects resulting therefrom using suitable calibration data, preferably as a function of the applied voltage V_{R}.

It is also conceivable to correct at least a possible saturation effect, for example at high radiation intensities, automatically by means of an automatic gain control system (AGC).

There are various ways of advantageously embodying and refining the teaching of the present invention. The reader is referred, for that purpose, on the one hand to the claims subordinate to claim 1, and on the other hand to the explanation below of preferred exemplifying embodiments of the invention with reference to the drawings. In conjunction with the explanation of preferred exemplifying embodiments of the invention with reference to the drawings, an explanation will also be given of generally preferred embodiments and refinements of the teaching. In the drawings:

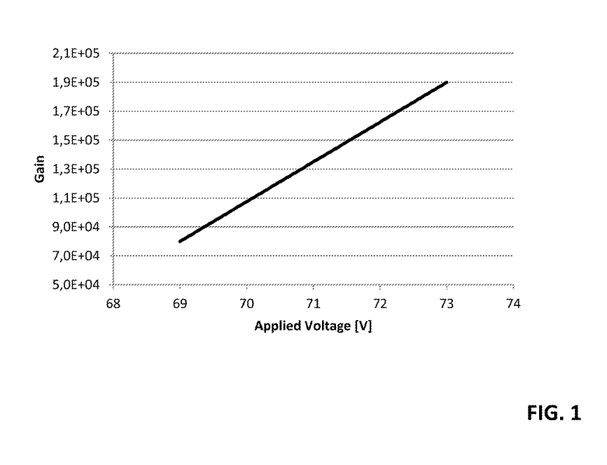

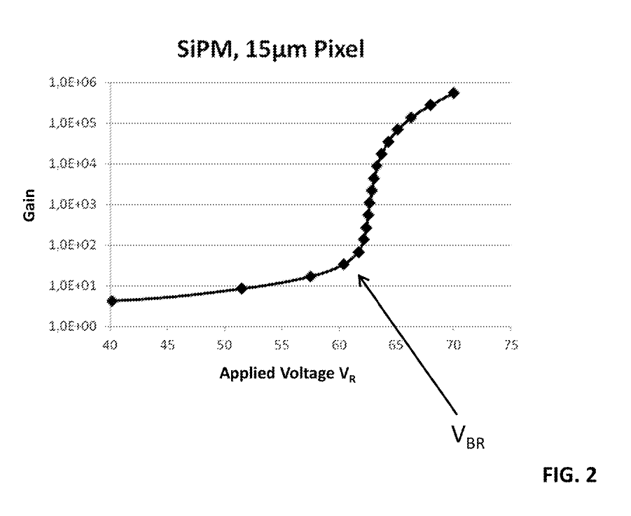

FIGS. 1 and 2 are diagrams showing the behavior of silicon photodiodes for voltages above (FIG. 1) and below and above (FIG. 2) the breakdown voltage;

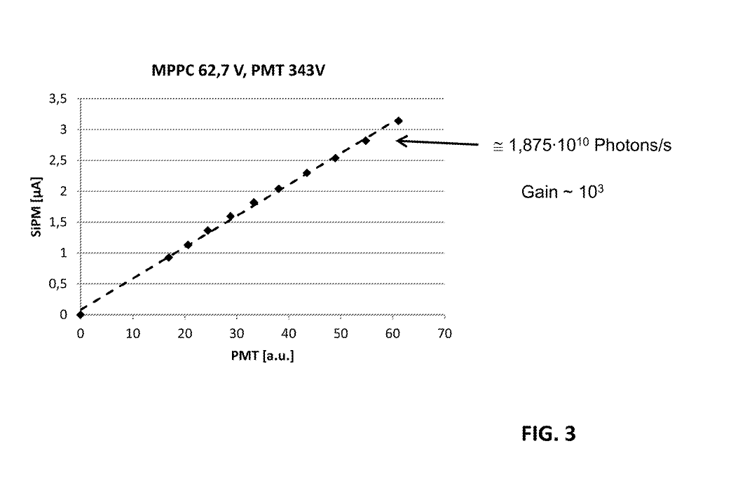

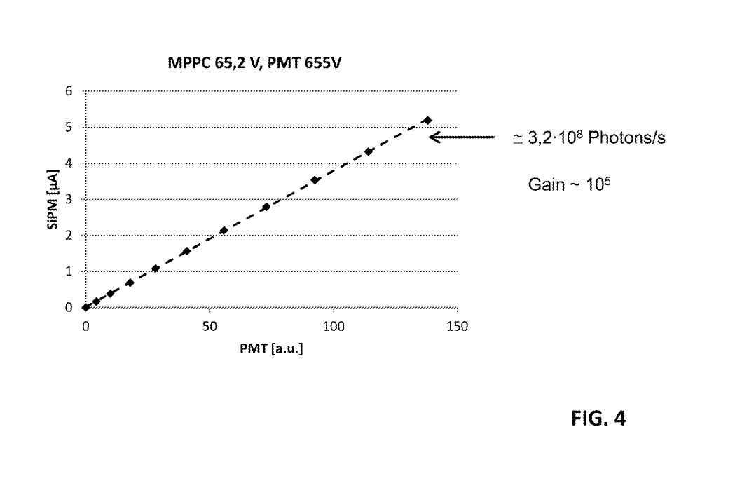

FIGS. 3 and 4 are schematic diagrams showing a comparison of the linearity criterion for two different gain settings (comparing a silicon photomultiplier with a photomultiplier assumed to be linear); and

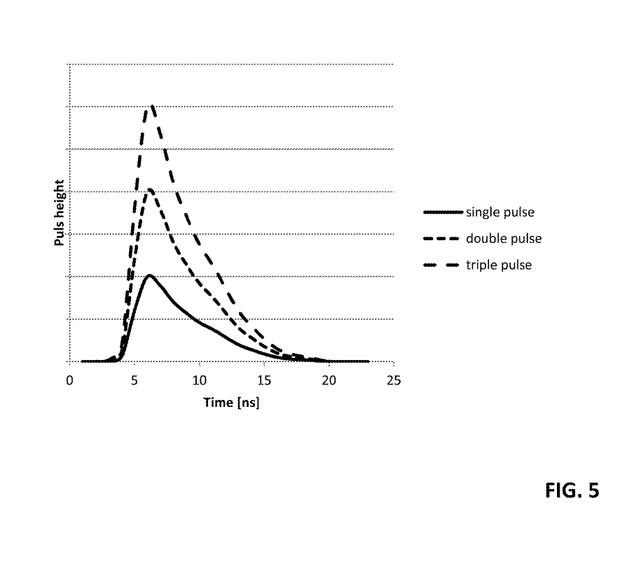

FIG. 5 is a schematic view of typical charge pulses or current pulses of APDS, which have a faster rise and a somewhat slower decay.

As discussed in the general description, there are in principle two possibilities for evaluating the signal of an SiPM, namely in the counting mode or the integration mode.

If one wishes to expand the dynamic range of an SiPM in terms of greater radiation intensities, all that can be used is the integration mode. Contrary to previous opinion, the applied voltage V_{R} can be varied in this mode, and with a correspondingly large number of incident photons it is possible to build up charge pulses into a measurable signal, namely by summing.

In accordance with what was discussed above, even in an SiPM the gain can be adjusted almost arbitrarily. For voltages V_{R} below the breakdown voltage V_{BR} the behavior of APDs transitions to normal photodiodes with no avalanche gain. Reference may be made in this regard to FIG. 1 and FIG. 2 with regard to a silicon photomultiplier.

A charge or signal can be adjusted for a specific radiation intensity by selecting the applied voltage V_{R}. In order to allow an SiPM to be used effectively even at lower applied voltages, not only is the signal level adapted to the incident maximum quantity of photons. The measured signal can in fact be approximately proportional to the incident quantity of photons. Corresponding linearity criteria are shown in

FIGS. 3 and 4 for two different gain settings, by comparison with a PMT assumed to be linear.

As already mentioned previously, with individual APDs it is known that the maximum count rates are on the order of 10⁷ cps (counts per second). This is attributable to the fact that after each charge pulse the APD has a certain dead time during which the voltage is built back up. With an SiPM the dynamics are greater than with an individual APD, since many APDs are connected in parallel. But even assuming an ideal case of 1,000 parallel and uniformly illuminated APDs in an SiPM, considerable saturation effects would need to be expected at intensities corresponding to what is depicted in FIG. 3.

Calculation example: The maximum signal according to FIG. 3 is approximately 3μA, i.e. 1.875·10¹³ electrons/s. At a gain of 1000, this corresponds to a detection rate of 1.875·10¹⁰ photons/s.

Because of the smaller area of each APD, charging takes less time than with an individual APD. FIG. 5 shows typical charge pulses or current pulses, which exhibit a fast rise (typically 0.1 to 5 ns) and a somewhat slower decay. The minimum possible dead time until a further avalanche discharge can take place should be approximately 10 to 30 ns.

To avoid repetition, reference is made to the general portion of the description and to the attached claims with regard to further advantageous embodiments of the apparatus according to the present invention.

Lastly, be it noted expressly that the exemplifying embodiments of the apparatus according to the present invention which are described above serve merely for discussion of the teaching claimed, but do not limit it to the exemplifying embodiments. The present invention is also applicable in particular, for example, to germanium photomultipliers and very generally for a semiconductor photomultiplier; and wherever a “silicon photomultiplier” (SiPM) is mentioned in this document, what is said there could correspondingly also relate to a germanium photomultiplier or to a semiconductor photomultiplier.

1. A method for increasing the dynamic range of a silicon photomultiplier (SiPM) in particular with regard to the detection of high radiation intensities, individual avalanche photodiodes usually being biased with a bias voltage V_{R} beyond a breakdown voltage V_{BR}, with the consequence of an avalanche discharge of electrons that define the output signal,
wherein the output signals resulting from an incident radiation intensity are adjusted by modifying the bias voltage V_{R}, the output signals being evaluated in the integration mode.

2. The method according to claim 1, wherein as a function of the incident radiation intensity, the applied bias voltage is adjusted to values below the breakdown voltage V_{BR} to above the breakdown voltage V_{BR}, no avalanche discharge of the avalanche photodiodes taking place at bias voltages below the breakdown voltage; and as the charge pulses per photon become smaller, the sum of the charge pulses of multiple photons is used as a measurable signal.

3. The method according to claim 1, wherein precalibrated values for the bias voltage V_{R}, with associated gains, are made available via a control software program.

4. The method according to claim 1, wherein operating mechanisms or operating elements that enable a preferably constant, continuous, or stepped gain adaptation are made available via a control software program.

5. The method according to claim 1, wherein a correction of any saturation effects is carried out automatically or manually via preferably voltage-dependent calibration data.

6. The method according to claim 1, wherein a correction of at least a possible saturation effect is carried out automatically by means of an automatic gain regulation system.
